(19) United States
(12) Patent Application Publication
(10) Pub. No.: US 2025/0169122 A1
(43) Pub. Date: May 22, 2025

(54) ULTRA-CLEAN VAN DER WAALS HETEROSTRUCTURES AND TECHNIQUES OF FABRICATION THEREOF

(71) Applicant: The Regents of the University of California, Oakland, CA (US)

(72) Inventors: Andrea Young, Goleta, CA (US); Liam Cohen, Goleta, CA (US)

(73) Assignee: The Regents of the University of California, Oakland, CA (US)

(21) Appl. No.: 18/841,877

(22) PCT Filed: Feb. 28, 2023
(86) PCT No.: PCT/US2023/014059

§ 371 Date: Aug. 27, 2024

Related U.S. Application Data
(60) Provisional application No. 63/314,623, filed on Feb. 28, 2022.

(51) Int. Cl. H10D 48/00; B82Y 10/00; G06N 10/40; H10D 48/01; H10D 62/80; H10D 62/85

(52) U.S. Cl. CPC H10D 48/3835; B82Y 10/00; G06N 10/40; H10D 48/031; H10D 62/85; H10D 62/882

(57) ABSTRACT

Disclosed are heterostructures that deploy one or more ultra-clean layers of van der Waals materials (VdW heterostructures). Further disclosed are techniques of fabricating VdW heterostructures that include patterning a conducting layer positioned on a substrate, separating, using a curved lifting surface, the patterned conducting layer from the substrate, and transferring the patterned conducting layer to a receiving stack of one or more layers while removing residual contaminants.

### RELATED APPLICATIONS

This application claims the benefit under 35 U.S.C. Section 119(e) of U.S. Provisional Application No. 63/314,623, filed Feb. 28, 2022, by Andrea Young and Liam Cohen, entitled “FABRICATION METHODOLOGIES FOR ULTRA-CLEAN VAN DER WAALS HETEROSTRUCTURES RELEVANT TO SCALABLE TOPOLOGICAL QUANTUM COMPUTING,” the entire contents of which is being incorporated herein by reference.

### STATEMENT REGARDING FEDERALLY SPONSORED RESEARCH AND DEVELOPMENT

This invention was made with Government support under Grant (or Contract) No. W911NF-17-1-0323, awarded by the United States Army Research Office, and Grant (or Contract) No. FA9550-20-1-0208, awarded by the Air Force Office of Scientific Research. The Government has certain rights in this invention.

### TECHNICAL FIELD

The instant specification generally relates to systems and techniques for creating electronic devices. Aspects of the instant specification relate to systems and methods for implementing quantum computing technology.

### BACKGROUND

Traditional quantum bits (qubits) are often implemented as two-level quantum systems that can be in a superposition state A|0 [symbol] +B|1 [symbol] of two quantum states, |0 [symbol] and |1 [symbol] , with continuously varying complex parameters A and B. Parameters A and B can be controlled using appropriately built hardware (quantum gates), which interact in a way that implements a specific desired quantum algorithm (via a sequence of unitary transformation of qubit states), and then measured using a type of read-out circuitry. Qubits are typically constructed in maximum isolation from their environment (e.g., stray electromagnetic fields, uncontrolled perturbations, etc.) to ensure long quantum coherence. Qubits can be implemented via electron and/or nuclear spins, superconducting Josephson junctions, quantum dots, cavity quantum electrodynamic systems, optical circuits, and so on. One approach to quantum computing utilizes collective degrees of freedom (made of many microscopic degrees of freedom) whose coherence is intrinsically immune (due to topological protection) to a large set of typical unwanted perturbations. Topological quantum computation uses operations of topologically protected non-Abelian anyon states, e.g., Majorana fermions in quantum wires, fractional quantum Hall states in two-dimensional electronic systems, and the like. Gate operations with non-Abelian qubit states can be implemented by “braiding” anyons (e.g., by moving anyons around each other), and readout of such states can be implemented by fusing anyons in a potential well and measuring a resulting charge distribution in the potential well.

### DESCRIPTION OF DRAWINGS

Aspects and implementations of the present disclosure will be understood more fully from the detailed description given below and from the accompanying drawings of various aspects and implementations of the disclosure, which, however, should not be taken to limit the disclosure to the specific aspects or implementations, but are presented for explanation and understanding purposes only.

FIG. 1 is a schematic illustration of a process of fabrication of ultra-clean van der Waals heterostructures, in accordance with at least one implementation.

FIGS. 2A-2D illustrate schematically patterning of gating layers using local anodic oxidation lithography for fabrication of van der Waals (VdW) heterostructures, in accordance with at least one implementation. FIG. 2A illustrates a technique of using an atomic force microscope (AFM) conductive probe to etch features into a conducting layer; FIG. 2B illustrates a feedback loop setup 220 for maintaining a set humidity; FIG. 2C shows an AFM topographic image of an example cross-shaped pattern of cuts in the conducting layer made of graphite using the local oxidation technique. FIG. 2D shows an AFM topographic image of the cross-shaped pattern of cuts of FIG. 2C cleaned, via van der Waals transfer, of carbon oxide residue. FIG. 2E shows an AFM topographic image of an example pattern of holes in a graphite layer using the local oxidation technique. FIG. 2F shows an AFM topographic image of the pattern of holes of FIG. 2F cleaned, via van der Waals transfer, of carbon oxide residue.

FIGS. 3A-3C show a transfer slide capable of detaching layers from underlying substrates and assembling the layers into VdW heterostructures, in accordance with at least one implementation. FIG. 3A is a schematic cross-sectional side view of the transfer slide. FIG. 3B is a schematic top view of the transfer slide. FIG. 3C is a photographic image of one example implementation of the transfer slide.

FIGS. 4A-4D illustrate a process of lifting a layer from a substrate using the transfer slide during fabrication of a VdW heterostructure, in accordance with at least one implementation.

FIGS. 5A-5C illustrate a process of lifting a patterned layer during fabrication of a VdW heterostructure, in accordance with at least one implementation.

FIG. 6A shows one example complex heterostructure that may be fabricated and assembled using the techniques of the instant disclosure, in accordance with at least one implementation. FIGS. 6B-6D show another example complex heterostructure that may be fabricated and assembled using the techniques of the instant disclosure, in accordance with at least one implementation. FIG. 6E shows an atomic force microscopy image of an example array of openings made in a graphite layer.

FIGS. 7A-7D illustrate a process of aggregating sets of fabricated layers into a single heterostructure using a curved lifting surface, in accordance with at least one implementation.

FIG. 8 is a flowchart of an example method of fabricating an ultra-clean heterostructure, in accordance with at least one implementation.

### DETAILED DESCRIPTION

Topological quantum computation may be implemented with materials that, on one hand, host suitable collective modes while, on the other hand, are sufficiently clean so that the collective modes are not destroyed or obscured by various material imperfections. Graphene and monolayer transition metal dichalcogenide semiconductors are one such platform, where the electronic structure allows for ground states hosting non-abelian anyons and the high crystalline purity puts practical control of these excitations within technological reach. Electrostatic gates provide a way for individual manipulation of electrically charged collective excitations. Aspects and implementations of the instant disclosure include (but are not limited to) systems and techniques for fabricating heterostructures made of various materials (e.g., two-dimensional materials) that enable efficient single-charge control without introducing imperfections and/or other contaminants. Existing technologies typically place local electrostatic gates on the nanometer scale either by additive manufacturing through deposition of amorphous metals, or via subtractive processing (etching) of completed heterostructures that are made of dielectric and metallic layers. In one example, implementations disclosed herein use an approach in which subtractive processing is applied to an isolated two-dimensional metal layer, such as graphite, and then the processed layer is transferred to a heterostructure having additional other dielectric and metallic layers. Aspects and implementations of the instant disclosure include methods for preserving integrity of sub-100 nm patterns while simultaneously removing, during the transfer process, various residues arising during the course of the subtractive processing.

The quantity that determines suitability of a specific system (material platform) for topologically protected quantum computing and information processing is the energy gap Δ that separates the ground state of the system from its excited states. In particular, the energy gap determines qubit error rate Γ driven by thermal activation processes, Γ∝exp(−Δ/k_{B}T), where T is the operating temperature and k_{B} is the Boltzmann constant. The energy gap Δ is a fundamental material property, with higher values of A resulting in longer coherence times and, therefore more feasible and efficient quantum gate operations. The maximum energy gap Δ may be determined by material properties of the specific material being used, yet may be significantly reduced by the presence of disorder in the material, e.g., crystal imperfections, substitution particles, placement of excess charges in or near the material, and the like. In turn, the amount of disorder depends on a specific synthesis (e.g., molecular beam epitaxy, exfoliation, chemical vapor deposition, and the like) technique used to manufacture the material(s) of the system. Additionally, disorder can be introduced during manufacture of control gates that are used to implement qubit control (e.g., via lithography and vacuum deposition, subtractive etching, and the like). Accordingly, even the materials with a considerable intrinsic energy gap Δ can lose this advantage as a result of a suboptimal assembly process, including but not limited to gate placement.

van der Waals (VdW) heterostructures are known for their ability to host a particularly rich category of topologically protected quantum states. VdW heterostructures, as used herein, should be understood as layered structures made of materials whose interlayer coupling is largely facilitated via relatively weak VdW forces. VdW materials, which constitute elemental layers of VdW heterostructures, should include materials that in a pure single-crystal form have VdW inter-layer bonding and covalent and/or ionic intra-layer bonding. For example, an elemental layer of a VdW heterostructure may be an atomically-thick two-dimensional crystal, e.g., an atomically-thick plane of carbon (graphene), metal chalcogenide such as niobium diselenide NbSe₂, molybdenum disulfide MoS₂, or tungsten selenide WSe₂, hexagonal boron nitride (hBN), and the like, and/or combinations thereof, such as rotationally-faulted graphene multilayers, heterobilayers of two different metal chalcogenide single crystals, and/or the like. Elemental VdW layers should be understood not to extend to thin films of materials that, in bulk form, have covalent and/or ionic interlayer bonding, e.g., such materials as diamond and alumina. Elemental layers in a VdW heterostructure may be stacked on top of each other, e.g., in an hBN/Graphene/hBN heterostructure, an atomically-thick hBN plane may be deposited on top of a single graphene layer that is deposited on another atomically-thick hBN plane. In various implementations, multiple atomically-thick layers of a given material may be stacked on top of each other. For example, a layer of a VdW heterostructure may include two planes of graphene (e.g., bilayer graphene), three planes of graphene (trilayer graphene), or four or more planes of graphene (referred to as graphite herein). Consecutive layers in a VdW heterostructure may have any suitable vertical atom arrangement (stacking), e.g., Bernal (AB. ABA, etc.) stacking, rhombohedral (ABC) stacking, twisted stacking, and/or the like. It should be understood that any number of layers (each layer being a single atom-thick layer or multiple atom-thick layers) of any number of different materials may be stacked to form a VdW heterostructure. In a VdW heterostructure, a stack of VdW materials may be supported by one or more non-VDW materials, e.g., a VdW stack may be supported by a silicon substrate or any other suitable substrate. Additionally, any other suitable material (e.g., silicon dioxide SiO₂) may be placed between the VdW stack and the substrate. VdW heterostructures may also be fabricated in a free standing geometry, without a substrate.

Although graphene and other two-dimensional electron materials in a VdW heterostructure can support collective excitations with large energy gaps Δ (e.g., Δ/k_{B}˜5K for the ν=−½ quantum Hall states in bilayer graphene), placement of control gates that use conventional additive and subtractive fabrication methods typically reduce the energy gap below its intrinsic value. For example, a dielectric layer may be deposited over one or more layers of graphene and metal plates (control gates) may be deposited on top of the dielectric layer. However, polycrystallinity of the deposited metal introduces a significant disorder potential acting within gated region of the graphene layer(s). In another example, a graphite layer can be used to implement control gates by cutting or etching (using a resist mask) the graphite layer into several electrically disconnected islands (that are used as gates). This, however, results in a disorder introduced to an underlying insulating layer (e.g., hBNetc.) along the etched regions (i.e., interfaces between differing electronic states whose high quality is advantageous for applications, including quantum computing), or throughout the bulk of the insulating layer, or both. This disorder often arises from the creation of dangling bonds on the surface of the insulator, even in cases where the insulating layer is a van der Waals materials with no dangling bonds in its pristine state. In yet another example, the graphite gates may be pre-patterned using lithographic techniques and subsequently integrated into a VdW heterostructure. The integration process typically uses a solvent that also introduces disorder (from solvent residue) to the graphite-hBN interface.

Aspects and implementations of the present disclosure address these and other challenges of the existing heterostructure fabrication technology by providing techniques for patterning gates on conductive layers without application of solvents and assembling stacks of conductive and non-conductive layers into heterostructures without introducing disorder into the layers. More specifically, in some implementations, a conductive (e.g., graphite) layer on a substrate may be patterned using a dry patterning process to form a plurality of regions where the conducting layer has been removed. In some implementations, the individual regions where the conducting layer has been removed may have total area less than 0.25 square microns. In some implementations, the regions may be electrically disconnected. Such dry patterning processes may include, e.g., local anodic oxidation patterning, focused ion or electron beam patterning, or patterning by immersion in a beam of focused ions or electrons with the layer to be patterned placed on a pre-patterned substrate. The patterned conductive layer may then be collected from the substrate and transferred onto a surface of an insulating (e.g., hBN) layer using a low-strain transfer process. In some implementations, the transfer process may use an elastomer stamp with a specially controlled radius of curvature covered with a thin, spin-coated polymer layer. The curved polymer-coated elastomer lifts the patterned conductive layer without causing large strains in the conductive layer and transfers the conductive layer onto a suitable support layer, e.g., a silicon substrate or a receiving stack of one or more previously assembled layers. This low-strain lifting process based on van der Waals bonding causes most of the impurities and other disorder centers, which may be introduced during dry patterning, to remain on the substrate and not transfer to the lifted conductive layer.

The same (or similar) low-strain transfer process may be used to assemble multiple conductive and/or insulating layers into a desired stack of layers (the target heterostructure). Some target heterostructures may include complex gate patterns that extend across multiple conductive layers and have to be assembled with high lateral accuracy. To overcome a tendency of individual VdW layers to slide with little friction relative to other VdW layers (e.g., a graphite layer sliding over an hBN layer), an alignment technique may be used that includes, in some implementations, bringing one conductive layer in the stack (e.g., the bottom layer) in contact with a high-friction substrate (e.g., SiO₂), capturing another conductive layer in the stack with a polymer-coated transfer slide and moving the transfer slide until a target sub-micron alignment of the conductive layers is achieved. Numerous additional techniques and variations of those techniques are disclosed herein.

The advantages of the disclosed implementations include (but are not limited to) fabrication of multi-layered heterostructures with complex control gate patterns and high electronic and structural quality resulting in significantly reduced amounts of disorder in the active layer as compared with the existing techniques. In particular, VdW heterostructures fabricated using the disclosed techniques may facilitate efficient local control of electrostatic potentials within one or more of active layers of the heterostructure and implement qubit gate operations. Additionally, high-quality VdW heterostructures enable accurate detection of motion of charge carriers and realization of reliable qubit readout operations.

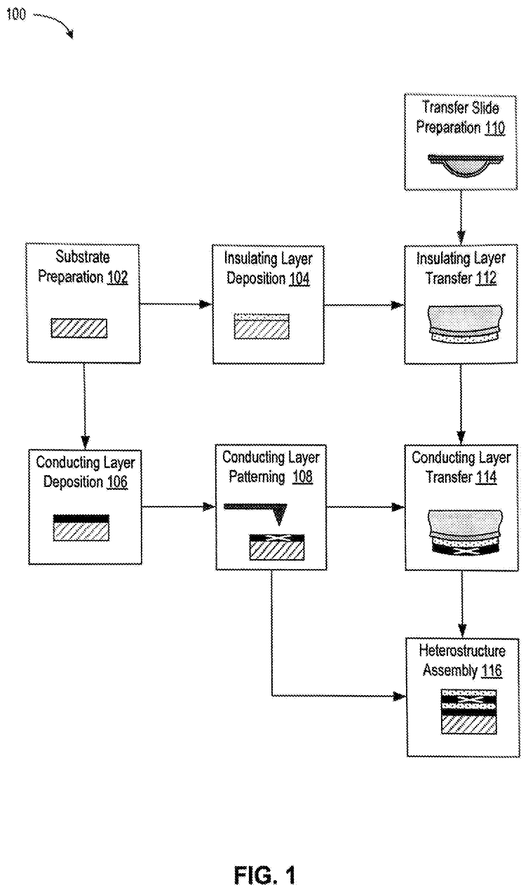

FIG. 1 is a schematic illustration of a process 100 of fabrication of ultra-clean van der Waals heterostructures, in accordance with at least one implementation. VdW heterostructures fabricated using process 100 may be supported by a substrate and may include one or more active (semi)conducting layers, one or more patterned conducting layers (e.g., gating layers, guiding layers, and the like), one or more insulating layers, but may also include other layers. Herein, an active layer is to be understood as a layer in which controllable motion or propagation of charges (e.g., individual electrons or collective charge excitations) may occur, e.g., responsive to an applied source-drain voltage or changes in the electrostatic potential induced by voltages applied to gating layers. Motion of charges in active layers may be spatially restricted subject to control via gating layers (and, in some implementations, guiding layers). Gating layers may include two or more electrically disconnected conducting islands capable of receiving different individual electric potentials (voltages) and creating a target electric (e.g., electrostatic) potential profile within the active layer(s) of the heterostructure. Gating layers may be made of metallic, semi-metallic, or semiconducting (e.g., doped semiconducting) materials. Guiding layers may include a single conductor island (although some guiding layers may include multiple conductor islands) with openings cut therein, which allows electric potentials created by the gating layers to access active layers positioned beyond (e.g., below or above) the guiding layers. In some implementations, a heterostructure may have one active layer. In some implementations, a heterostructure may have multiple active layers. In some implementations, active layer(s) may be unpatterned (although this is not a requirement). In some implementations, an active layer may support a two-dimensional electron gas (e.g., may be a graphene-based or transition metal dichalcogenide-based active layer) or multiple instances of coupled two-dimensional electron gases (e.g., may be a bilayer graphene active layer, a trilayer graphene active layer, and the like). In some implementations, an active layer may support a quasi-two-dimensional electron gas (e.g., may be a thin film of graphite).

In some implementations, process 100 may include a substrate preparation stage 102. Substrate preparation stage 102 may grow ingots, e.g., silicon ingots, grind the grown ingots to a desired size, slice the ingots into raw substrates (wafers) of a desired thickness, bevel the substrates, polish (mechanically and/or chemically) the substrates, clean the substrates, remove impurities that reside on the surface of the substrates, and/or the like. Substrates may be inspected, and the substrates that do not conform to the specification of process 100 may be discarded or diverted for further processing. The substrates may be silicon substrates, silicon carbide substrates, or substrates made of any other suitable materials. In some implementations, the substrates may be crystalline (e.g., single-crystal or polycrystalline) substrates. In some implementations, the substrates may be amorphous. In some implementations, the substrates may be coated with one or more protective and/or insulating layers, e.g., silicon dioxide SiO₂ layers, and/or the like.

Substrates fabricated by substrate preparation stage 102 may be processed by an insulating layer preparation stage 104, which places one or more insulating layers (e.g., hBN layers) on the substrates. A conducting layer preparation stage 106 may similarly place conducting layers (e.g., graphite layers, graphene layers, etc.) on top of the substrates. In some implementations, a conducting layer may be placed on a previously placed insulating layer. Operations of insulating layer preparation stage 104 and/or conducting layer preparation stage 106 may deploy any suitable deposition techniques, growth techniques, exfoliation techniques, and/or the like, or any combination thereof. A conducting layer patterning stage 108 may imprint a pattern of gates to one or more conducting layers, e.g., by cutting through the depth of a respective conducting layer within at least a region of the respective conducting layer whose electrically separated banks are to be held at different electric potentials (voltages) for implementing control of the active layers.

A transfer slide preparation stage 110 may fabricate a slide capable of adhering to various insulating and/or conducting layers and lifting such layers from the substrates on which the corresponding layers are residing. In some implementations, a transfer slide may be made of a combination of one or more organic materials, e.g., the bulk of a transfer slide be made from a one organic (e.g., polymer) material and then coated with a highly adhesive layer of another organic material.

The fabricated transfer slides may be used to pick up (lift) insulating layers (at insulating layer transfer stage 112) and patterned conducting layers (at conducting layer transfer stage 114). At a heterostructure assembly stage 116, the lifted layers may be placed on top of other layers, e.g., insulating layers and/or unpatterned conducting layers grown or deposited on other substrate(s), and/or patterned conducting layers previously transferred by the transfer slide. Heterostructure assembly stage 116 may further include aligning of various patterned conducting layers relative to each other. For example, a patterned conducting layer with a pattern of gates fabricated during stage 108 may be aligned relative to another patterned conducting layer, e.g., relative to openings of a passive guiding layer that guides electric field to a target region of an active layer.

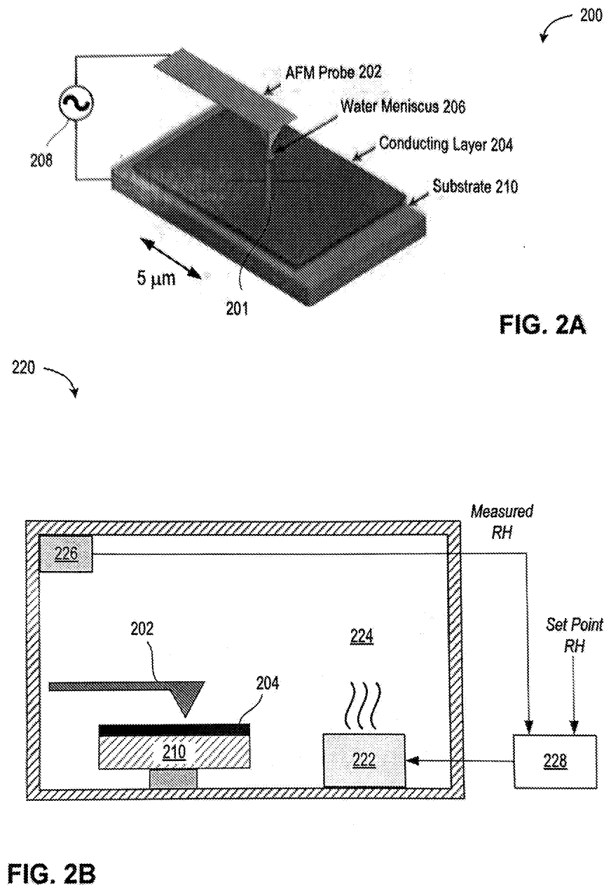

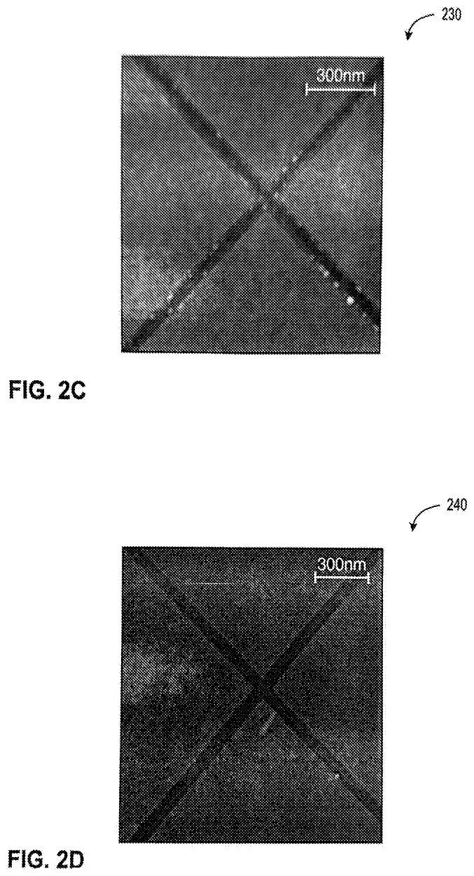

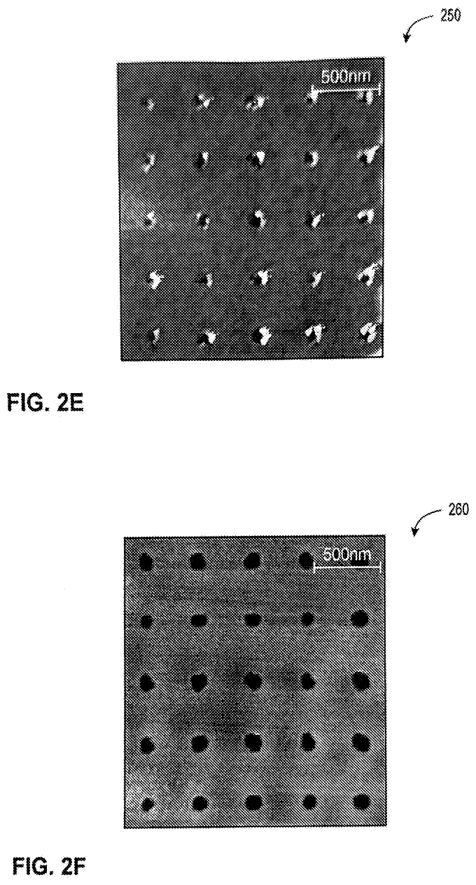

FIGS. 2A-2D illustrate schematically patterning of gating layers using local anodic oxidation lithography 200 for fabrication VdW heterostructures, in accordance with at least one implementation. Local oxidation lithography 200 utilizes the fact that certain non-spontaneous oxidation-reduction reactions may be catalyzed by an applied potential gradient. In particular, FIG. 2A illustrates a technique of using an atomic force microscope (AFM) conductive probe 202 to etch features, e.g., pattern of cuts 201, into a conducting layer 204, e.g., a graphite layer. As AFM probe 202 is brought close to the surface of conducting layer 204, a small water meniscus 206 condenses between AFM probe 202 and the surface of conducting layer 204 due to capillary forces. If a voltage 208 is applied between the tip of AFM probe 202 and a substrate 210 supporting conducting layer 204, the induced electric field causes one or more chemical reactions to occur at an interface between the surface of conducting layer 204 and water meniscus 206. For example, in the instance of graphite conducting layer 204, the following oxidation reactions may occur:

C+H₂O→CO+2H(+)+2e(−);

C+2H₂O→CO2+4H(+)+4e(−).

Additionally, a concurrent reduction reaction may occur at an interface between AFM probe 202 and water meniscus 206: 2H₂O+2e(−)→H₂+2OH(−). By controlling speed and direction of motion of AFM probe 202, lines of graphite oxide may be patterned in a controlled fashion. In some implementations, a static (DC) negative voltage may be applied between AFM probe 202 and substrate 210. In some implementations, an electrode may be deposited onto the substrate 210 so that when the conducting layer 204 comes into contact with substrate 210, layer 204 may be electrically grounded to facilitate the controlled oxidation reaction. In some implementations, conducting layer 204 may be deposited on a bare substrate 210 with no underlying target pattern. In such implementations, the oxidation reactions may be facilitated by an application of an AC voltage 208 with oxidation reaction occurring during negative voltage swings (half-periods) of voltage 208. In some implementations, frequency of AC voltage 208 may be between 10-10,000 kHz, e.g., may be around 100 kHz. Such frequencies are, on one hand, high enough for a displacement current to efficiently flow through conducting layer 204 even when conducting layer 204 is not in direct contact with any electrode (e.g., with no underlying metallic pattern) while, on the other hand, are sufficiently low compared with the rates of the oxidation/reduction reactions.

In some implementations, one or more features etched onto conducting layer 204 may have sub-micron sizes. In some implementations, one lateral dimension of etched feature(s) may be smaller than 500 nanometers. It should be understood that the dimensions of FIG. 2A are intended as in illustration and that actual dimensions of etched features may be less than 300 nm, less than 200 nm, less than 100 nm. In some implementations, the dimensions may be more than 500 nm, e.g., more than 700 nm, more than 800 nm, more than 1 μm, or even more. In one example implementation, the total area of an individual etched feature may be smaller than 0.25 square microns, e.g., a circular etched feature may have a radius that is smaller than 0.275 microns, or a trench may have a length of 1 micron or less and a width smaller than 250 nanometers. In one example implementation, the total area of an individual remaining feature may be smaller than 0.25 square microns, e.g., a circular feature with radius smaller than 0.275 microns may remain after subtraction. In one example implementation, a ribbon may have a length of 1 micron or less and a width of 250 nanometers or less. In some implementations, local oxidation lithography 200 may be performed efficiently while the relative humidity (RH) is maintained at or above 50%. FIG. 2B illustrates a feedback loop setup 220 for maintaining a set RH. As shown in FIG. 2B, a vapor generator plant 222 may cause a water vapor to be introduced into an environment of a processing chamber 224 where the oxidation lithography process takes place. In some implementations, vapor generator plant 222 may include a beaker of deionized water placed on a heater plate whose temperature is maintained at 100° C. (or slightly higher) or at some other temperature (e.g., at a pressure-dependent boiling temperature, or slightly higher). A humidity sensor 226 may continuously (or at periodic time intervals) detect RH of the environment and provide the detected RH to a humidity controller 228. A second input into humidity controller may be a set point RH value RH_{SET}, e.g., 50%, 55%, or any other suitable RH value. Humidity controller 228 may include a comparator circuit that controls a power signal provided to the heater plate of vapor generator plant 222, e.g., allowing the power signal to reach the heater plate if RH<RH_{SET} and turning the power signal off provided that RH>RH_{SET}. In some implementations, AFM probe 202 may be confined inside a vibration isolation hood, allowing the humidity to remain stable at the set RH point for periods that may be 12 hours long or even longer to ensure a consistent and repeatable environment for local oxidation lithography 200.

In some implementations, local oxidation lithography 200 may use a Bruker Dimension®) Icon™ AFM with platinum-iridium coated conducting AFM probes (Arrow-NcPt). Conducting layer 204 may be a graphite layer prepared by mechanical exfoliation onto a conducting Si substrate 210 with an oxide layer thereon having thickness of 1-350 nm. In some implementations, the conducting 204 may be a single crystal graphene of 2 layers (bilayer graphene) or 3 layers (trilayer graphene), or a single crystal graphite having four or more layers, or a conducting transition metal dichalcogenide. Line width d of local oxidation lithography 200 may be of the order of d≈50-120 nm (controllable by using AFM tips of different thickness) for several nm-deep graphite conducting layer(s) 204. For the crossing pattern of cuts, the tip-to-tip diagonal distance may, therefore, be d√\sqrt{2}≈70-170 nm, making it possible to implement various nanoscale devices, e.g., quantum point contacts of the corresponding size. In one possible implementation, to realize a quantum point contact, the four parts of the patterned graphite layer may be held at different voltages. For example, the north tip and the south tip may be held at negative voltage−V₁ whereas the west tip and the east tip may be held at a positive voltage +V₂. As a result, the electrostatic potential below the crossing pattern of cuts within some plane (e.g., an active plane of the heterostructure) positioned at depth h below the graphite layer may be φ(x,y)≈α(h)x²−β(h)y², such that electron motion may be allowed along the west-east direction (x-axis) and prevented along the north-south direction (y-axis), with the parameters α(h) and β(h) that depend on the depth h and controlled by the voltages V₁ and V₂. Characterization measurements performed on quantum point contacts fabricated using methods disclosed herein show that the electrostatic potential in the active layer caused by application of voltages to the patterned graphite layer in the central 100 nm by 100 nm region may be within 10 μV from the potential inferred from model electrostatic simulations for a conducting layer with ideal geometric patterning. In a spatially repeated system of quantum point contacts (or similar devices fabricated using patterned graphite layers), individual charges may be trapped in a superlattice of quantum wells. This includes devices where the charges are associated with collective excitations of many-body electronic states, including but not limited to fractional quantum Hall states (in which the energy gap may as small as 0.5 meV). In contrast, structures produced by conventional methods, e.g., subtractive processing of a van der Waals layer after stack assembly or structures where a patterned layer is deposited by metal evaporation typically introduce uncontrolled electrical potentials greater than 1 mV to the active layer.

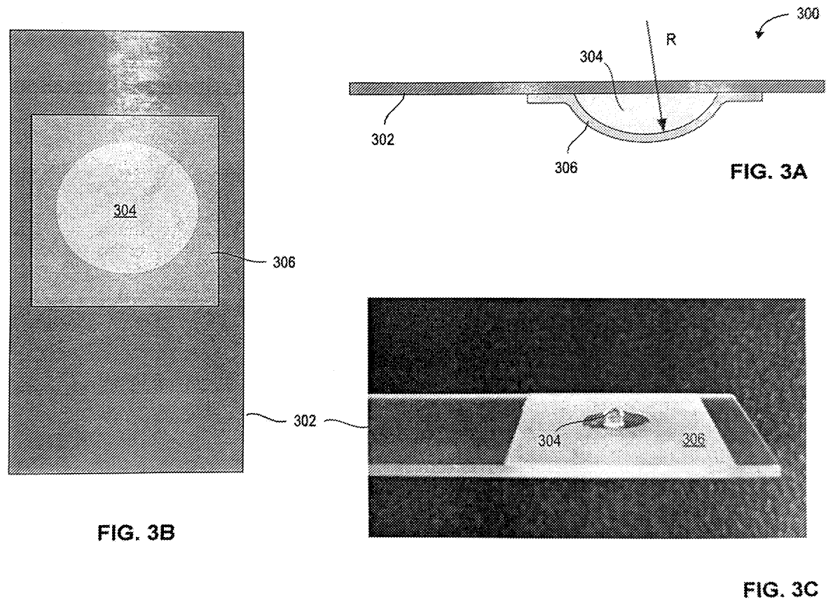

FIG. 2C shows an AFM topographic image 230 of an example cross-shaped pattern of cuts in conducting layer 204 made of graphite using the local oxidation technique. As illustrated with FIG. 2C, AFM local oxidation lithography technique leaves some amount of a carbon oxide residue (white dots in the image of FIG. 2C) along the cuts that gives rise to some amount of disorder. The amount of this residue may be reduced by lifting conducting layer 204 off substrate 210 using a combination of a dome-shaped polymer lifting surface and an insulator VdW material (e.g., hBN) adhered to the lifting surface, e.g., as described in more detail in conjunction with FIG. 3. FIG. 2D shows an AFM topographic image 240 of the cross-shaped pattern of cuts of FIG. 2C cleaned, via van der Waals transfer, of carbon oxide residue. In particular, as illustrated with FIG. 2D, the carbon oxide residue tends not to adhere to the insulating layer thus effectively cleaning the gating layer(s) in the course of the layer pickup and transfer. FIG. 2E shows an AFM topographic image 250 of an example pattern of holes in a graphite layer using the local oxidation technique. FIG. 2F shows an AFM topographic image 260 of the pattern of holes of FIG. 2F cleaned, via van der Waals transfer, of carbon oxide residue.

In some implementations, a focused ion beam (FIB) or a focused electron beam direct-write lithography may be used instead of (or in addition to) local oxidation lithography 200. More specifically, FIB may deploy a source of ions (e.g., a plasma source) and an accelerating column that accelerates and focuses ions towards a sample, which may include a silicon substrate, a silicon oxide coating, and a conducting layer being patterned. The kinetic energy of the focused accelerated ions is used to break atomic bonds of the conducting layer to selectively remove parts of the conducting layer that come in contact with the ion beam. In some implementations, Gallium ions may be used. In some implementations, Helium ions may be used. In some implementations, intermediate-mass ions that are heavier than Helium but lighter than Gallium may be used, such as doubly ionized Si ions, e.g., produced using a Velion Raith FIB system, or any other suitable system. The intermediate-mass ions may have a significantly higher etching power than the Helium ions while being lighter and, therefore, allowing easier and more accurate collimation and focusing, than the Gallium ions. Additionally, intermediate-mass ions may be less likely than the Helium ions to diffuse out of the substrate and distort other layers of the target heterostructure. In particular, FIBs that use Silicon ions may achieve cuts with a minimum thickness that is comparable or less than the thickness achievable when AFM oxidation lithography 200 is used for dry-patterning of graphite. In some implementations, high-energy electron beams may be used with beam energies at or larger than 2 keV but smaller than 250 keV. High-energy electron or ion beams may achieve cuts with a minimum dimension (e.g., thickness) that is comparable with or even less than the thickness achievable with use of AFM oxidation lithography 200 for dry-patterning of graphite.

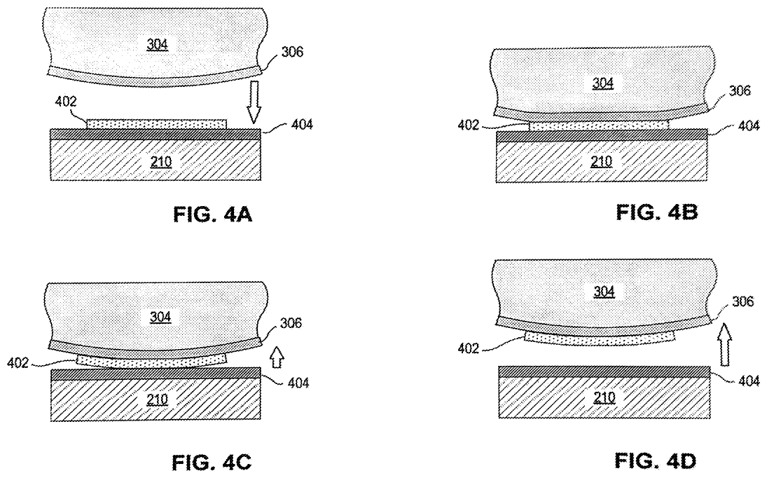

In some implementations, the described techniques (e.g., AFM local oxidation lithography, FIB lithography, electron beam lithography etc.) may be used to perform only a part of the patterning process prior to layer transfer, e.g., to keep at least some structural integrity of the patterned layer(s) and thus minimizing the likelihood of tearing during the layer transfer process. For example, a central (or some other) region, where motion of charges is to occur during device operations, may be patterned prior to the layer transfer process, since the layer transfer process is also simultaneously cleaning the layers from unwanted residue of the patterning process. Subsequently, after performing the layer transfer process (e.g., as disclosed below in conjunction with FIGS. 4-6), the patterning may be extended to other areas of the layer(s), e.g., all the way to the edges of the layer(s), where absence of disorder is less important for efficient device operations.

FIGS. 3A-3C show a transfer slide 300 capable of detaching layers from underlying substrates and assembling the layers into VdW heterostructures, in accordance with at least one implementation. FIG. 3A is a schematic cross-sectional side view of transfer slide 300. FIG. 3B is a schematic top view of transfer slide 300. FIG. 3C is a photographic image of one example implementation of transfer slide 300. Example transfer slide 300 may including a dome-shaped lifting surface to reduce strain during detachment and transfer of layers, compared with flat-shaped transfer slides. In some implementations, transfer slide 300 may have a frame 302, which may be made of any suitable material, e.g., glass, quartz, and the like. A dome 304 may be mounted on frame 302. In some implementations, dome 304 may be made of a polymer material, e.g., Polydimethylsiloxane (PDMS), Poly(methyl methacrylate) (PMMA), Polystyrene, Poly(lactic-co-gly colic) acid (PLGA), thiol-enes, and/or thermoplastics, and may have a radius of curvature R that is controlled during a dome fabrication process. In some implementations, the radius of curvature R may be between 2 mm and 6 mm. In some implementations, dome 304 may further be coated with a coating film 306. Coating film 306 may be made of another polymer, such as a polycarbonate laminate, e.g., Bisphenol-A polycarbonate (BPA), Polyvinyl alcohol (PCA). Polypropylene Carbonate (PPC), or even Polyvinylidene chloride (PVDC). In some implementations, coating film 306 may have a high chemical quality and morphological uniformity. In some implementations, coating film 306 may envelop dome 304 and a portion of frame 302.

Conventional techniques for making BPA thin films include dissolving BPA in chloroform and pressing the BPA between two glass slides. This, however, results in films that are unrepeatable and structurally non-uniform. This structural non-uniformity can cause some areas of the BPA to selectively adhere to the layers being lifted, causing non-uniformity in lifting velocity and tearing of the layers. Better results may be achieved with dissolving BPA in cyclopentanone. In some implementations, an ultrasonic wand may be used to facilitate the dissolution process. Since cyclopentanone has a lower vapor pressure than chloroform, the dissolved BPA may be spun on a silicon chip into a film of a very high uniformity.

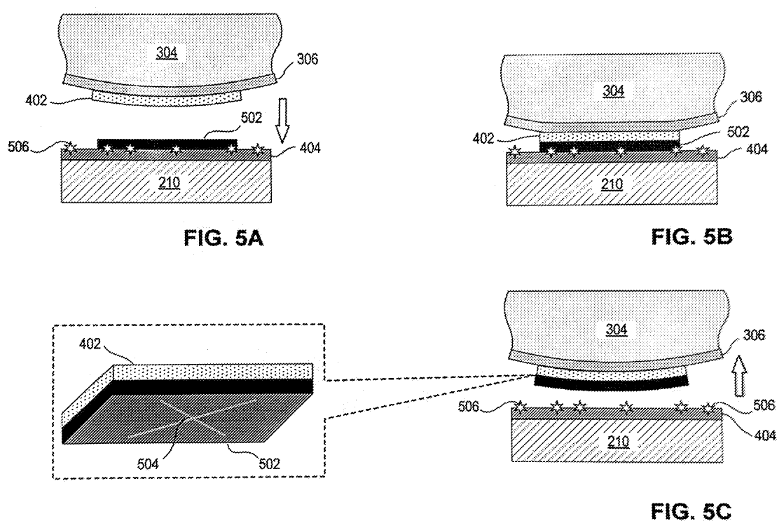

The dome-shaped form of the lifting surface and/or the uniformity of the spun-BPA laminate used as the coating film 306 facilitates dramatic reduction of strain during assembly of VdW heterostructures while also reducing stochastic changes in the lifting speed. This makes possible a damage-free transfer of micro-textured gating layers into a VdW heterostructure by efficiently mitigating mechanical strain so that the patterned micro-structures do not tear. Additionally, when a patterned conducting layer is lifted by the coating film 306, e.g., with an insulator VdW layer (e.g., hBN) previously adhered thereto (as described in more detail below in conjunction with FIGS. 5A-C), the oxidized residue does not attach to the insulating layer. This enables implementation of virtually disorder-free micro-structured gate patterns.

The following example process of preparing transfer slide 300 is presented for the purpose of illustration and not limitation. In one example implementation, a 100 mm petri-dish with 8 grams of cured PDMS solution may be prepared. The 10:1 weight ratio of Sylgard 184 PDMS to a curing agent. After mixing thoroughly a solution of the PDMS and the curing agent, the mixture is placed in the petri-dish and (fully) cured for 24 hours under vacuum and ambient temperature conditions. Another 100 mm petri-dish may be similarly prepared with 3 grams of PDMS with the same (or similar) ratio of the PDMS to the curing agent and then (semi) cured for 60 minutes. A toothpick or a small pipette may then be used to place a droplet of the semi-cured PDMS onto a transfer slide 300 frame (e.g., a glass plate) while the transfer slide 300 frame is in a horizontal position. A 3 mm hole punch may then be used to cut out a 3 mm cylinder from the fully cured PDMS batch. The cut-out cylinder may subsequently be placed onto the droplet of the semi-cured PDMS on transfer slide 300. Another toothpick or a small pipette may be used to place a second droplet of the semi-cured PDMS on top of the 3 mm PDMS cylinder forming dome 304 on transfer slide 300. The PDMS may then be cured for 24 hours.

The curvature of dome 304 may be measured, e.g., using the method of Newton's rings. More specifically, to measure the radius of curvature R of dome 304, dome 304 assembly may be treated as a lens. Dome 304 may be placed next to a reflective substrate and a series of circular interference fringes—Newton's rings—may be observed in an optical microscope, caused by thin-film diffraction with the air between the reflecting surface and dome 304. Diameters of successive Newton's rings (constructive interference fringes) for a fixed wavelength A of the diffracted light may be determined by the following formula (if illumination is from above),

$${D}_{n} = \sqrt{2 ( 2 n - 1 ) λ R} .$$

By measuring diameters of multiple Newton's rings D₁, D₂ . . . , and fitting the measured diameters using this formula, a radius of curvature R of dome 304 may be determined. Radius of curvature R directly influences the amount of strain that occurs during layer transfer. Larger radii R lead to smaller amounts of strain but a reduction in residue-cleaning abilities of dome 304.

FIGS. 4A-4D illustrate a process of lifting a layer from a substrate using transfer slide 300 during fabrication of a VdW heterostructure, in accordance with at least one implementation. The lifting process illustrated in FIGS. 4A-4D is capable of maintaining structural integrity of various layers that may be lifted and transported in the course of fabrication and assembly of multi-layer heterostructures, including layers with nanoscale or sub-micron patterns (e.g., having size of 10-100 nanometers, or total area less than 0.25 square microns, e.g., as depicted in FIGS. 2C-2F). As illustrated in FIG. 4A, lifting and transferring an insulating layer 402 (e.g., an insulating VdW layer, such as a layer having one or more hBN atomic planes) may be accomplished using transfer slide 300 disclosed in conjunction with FIGS. 3A-3C above, or using some other dome-shaped lifting surface, to ensure a smooth continuous jerk-free) lifting that maintains structural integrity of lifter layers. Prior or concurrently with the transfer slide 300 being brought in contact and pressed into insulating layer 402 (FIG. 4B), dome 304 and coating film 306 (e.g., polycarbonate), may be heated, e.g., up to temperatures about 80-120° C., causing insulating layer 402 to adhere to coating film 306. This enables lifting of insulating layer 402 off substrate 210 (or substrate coating 404, if present), as illustrated in FIGS. 4C-4D, as insulating layer 402 adheres to coating film 306.

The control of strain forces may be achieved by selecting the dome 304 having a target radius of curvature R. Smaller radii of curvature R result in a higher strain during layer transport and heterostructure assembly. Higher strains are more likely to cause rips or tears in insulating layer 402 (or other layers being lifted/transported). Correspondingly, in some implementations, the radius of curvature R may be at or above 2 mm. On the other hand, having some amount of strain (and therefore, radius of curvature below a certain limit, e.g., R<5-6 mm, may be beneficial for self-cleaning of layers during lifting. Having a curvature is further beneficial for pushing various residue that may be present on the layers (e.g., left on the layers after the layer fabrication process) away from the central portion of the heterostructures, e.g., a region where motion of charges is to occur during device operations.

Sharp vertical movements of transfer slide 300 may still be detrimental to the integrity of the layers during lifting/transfer, since such sudden movements introduce undesired strain, which can cause the pre-patterned conductor (e.g., gating) layers to tear. Coating film 306 helps with reduction of sensitivity of the lifting/transfer process to such sudden movements, as coating film 306 smoothly laminates and delaminates over the layers and dampens, to a significant degree, sudden motions of the transfer slide 300.

FIGS. 5A-5C illustrate a process of lifting a patterned layer during fabrication of a VdW heterostructure, in accordance with at least one implementation. Patterned conducting gating layers of VdW heterostructures may be lifted in a manner similar to that illustrated in FIGS. 4A-4C. As illustrated in FIG. 5A, lifting a patterned conducting layer 502, e.g., a VdW layer, such as a patterned graphite layer, may be performed using transfer slide 300 that includes dome 304 covered with coating film 306. In some implementations, transfer slide 300 may have previously picked up insulating layer 402, e.g., an insulating VdW (such as hBN) layer, which is adhered to coating film 306. As the slide is pressed towards substrate 210 (cf. FIG. 5B), patterned conducting layer 502 adheres to the previously lifted insulating layer 402. Lifting the slide causes patterned conducting layer 502 to disengage from substrate 210 and maintain contact with insulating layer 402 (cf. FIG. 5C). As the callout portion of FIG. 5C illustrates, the curved shape of dome 304 and coating film 306 allows patterned conducting layer 502 to maintain an undisturbed pattern 504 (which may have been lithographed using one of the techniques described in conjunction with FIGS. 2A-2C). A suitably chosen curvature R of the dome 304 reduces lateral strains acting within patterned conducting layer 502 and significantly reduces the likelihood that pattern 504 is ripped apart or deformed during the lifting part of the transfer process.

Additional benefits of the lifting process performed using dome-equipped transfer slide 300 include cleaning of patterned conducting layer 502 of residue 506 that may have been trapped between patterned conducting layer 502 and substrate 210. For example, residue 506 may include carbon oxide and/or carbon dioxide residue accumulated during the local oxidation lithography of pattern 504. As the slide is lifted (cf. FIG. 5C), residue 506 remains attached to the surface of substrate 210 and does not adhere to the lifted patterned conducting layer 502.

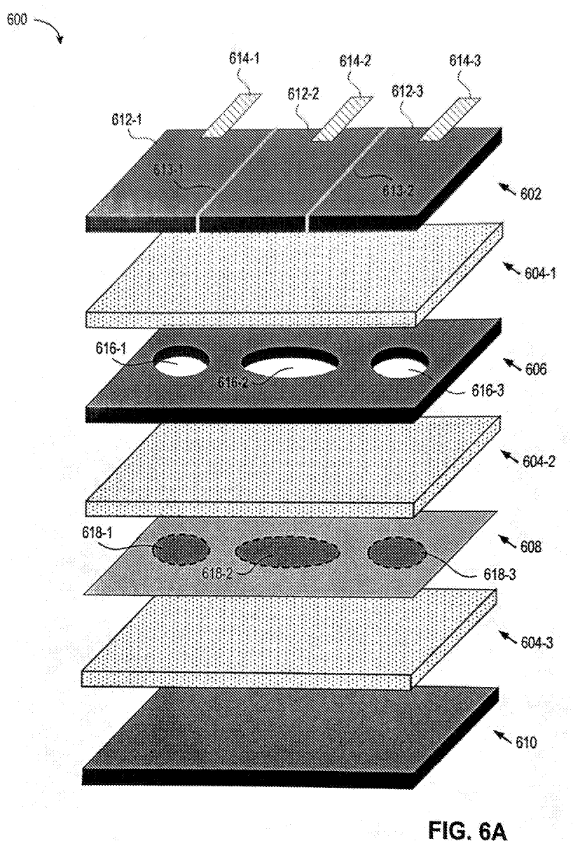

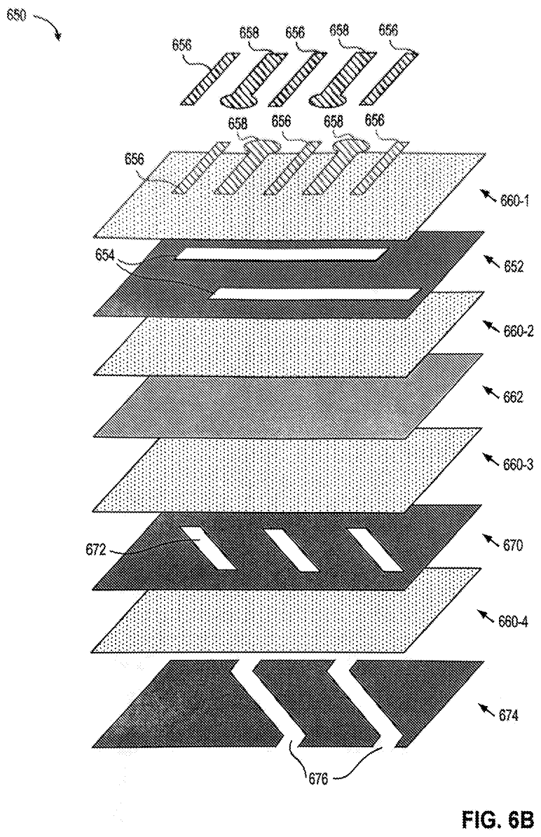

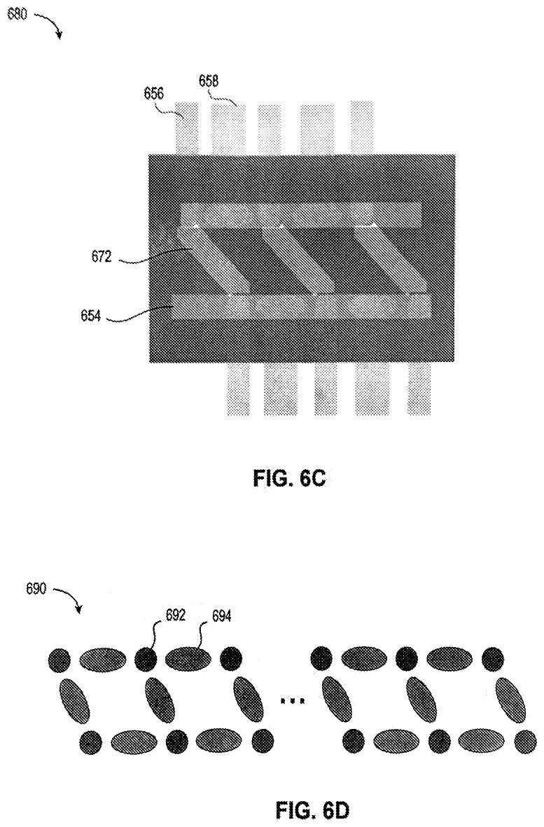

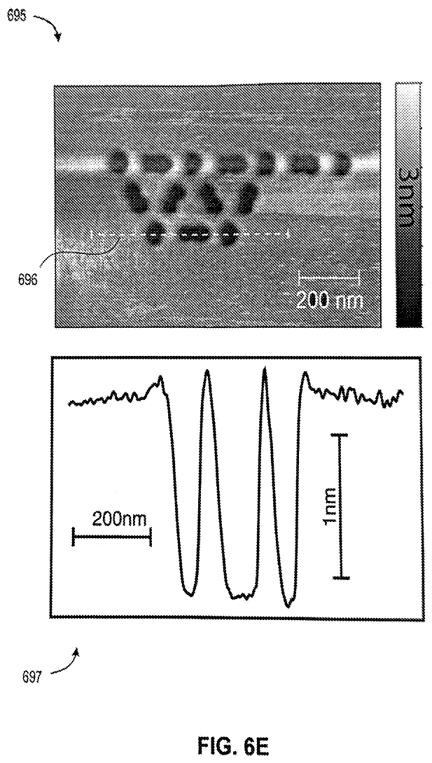

Certain complex heterostructures use, during operation, various multi-featured electrostatic profiles that may be achieved using multiple patterned gating conducting layers, e.g., graphite layers with one or more gating layers being internal to the heterostructures (e.g., gating layers that are sandwiched between insulating layers). FIG. 6A shows one example complex heterostructure 600 that may be fabricated and assembled using the techniques of the instant disclosure, in accordance with at least one implementation. Heterostructure 600 includes a patterned gating layer 602 patterned into multiple electrically isolated conducting gates 612-1, 612-2, 612-3, separated by cuts 613-1, 613-2. The isolated gates may be separately contacted with electrodes 614-1, 614-2, 614-3, which may be individually held at different voltages (e.g., using a voltage source not explicitly depicted in FIG. 6A). In some implementations, electrodes 614-j may be deposited at distant regions of conducting gates 612-j where presence or absence of disorder is less important for the functionality of heterostructure 600. Heterostructure 600 further includes multiple insulating layers 604-1, 604-2, 604-3 separating various conducting layers. Heterostructure 600 further includes a guiding layer 606, which may be patterned. Heterostructure 600 further includes an active layer 608 and a bottom gate layer 610, which may be unpatterned. Active layer 608 may be any conducting or semiconducting layer whose electrical conduction can be controlled by electrostatic potential applied to various gating layers. In some implementations, active layer 608 may host a two-dimensional electron gas. For example, active layer 608 may be a bilayer graphene layer whose electron band spectrum has an energy gap (e.g., controlled by a vertical electric field). Bottom gate layer 610 may be held at such electric potential that the chemical potential of electrons in active layer 608 is within the energy gap in most parts of active layer 608. Guiding layer 606 may have openings 616-1, 616-2, 616-3, etc., which allow access of the electric field of the respective gates 612-1, 612-2, 612-3, etc., to active layer 608. Electrostatic potential within active layer 608 may be locally lowered (or raised) causing the chemical potential to be within the conduction band (or the valence band) of electrons in active layer 608. As a result, active layer 608 may host multiple independent and separately controlled isolated conducting islands or quantum dots (QDs) 618-1, 618-2, 618-3, etc. Further control of QDs 618-j may be achieved by additional gates that may be patterned in gating layer 602 (or additional gating layers not shown in FIG. 6A for conciseness and ease of viewing). Numerous other heterostructures may be fabricated using the techniques of the instant disclosure, including but not limited to quantum point contacts, quantum wires or other one-dimensional or quasi-one-dimensional electron systems, structures supporting edge states, and the like.

FIGS. 6B-6D illustrate another example complex heterostructure 650 that may be fabricated and assembled using the techniques of the instant disclosure, in accordance with at least one implementation. FIG. 6B depicts a series of electrostatically confined quantum dots is created in an active layer 662, with the aid of four distinct gating layers 674, 670, 652, and a layer with electrodes 656 and 658. The gating layers are separated from each other and from active layer 662 by insulating layers 660-1, 660-2, 660-3, and 660-4. Heterostructure 650 may be used, through the application of voltages to the distinct patterned conducting layers, to generate a repeating potential profile in active layer 662. Electrodes 656 and 658 may be fabricated from a patterned single-crystal layered material, from an evaporated metal, or any other suitable material. In some implementations, electrodes 656 have a width of 10-60 nm and electrodes 658 have a width of 20-200 nm. In some implementations, a distance between adjacent electrodes 656 and 658 may be 20-100 nm. In some implementations, electrodes 656 and electrodes 658 may form multiple arrays (two arrays are shown in FIG. 6B). Within a given array, electrodes 656 and electrodes 658 may be intermingled, and electrodes 656 and 658 in different arrays may have a lateral offset in the corresponding repeated structures, as shown. Each of electrodes 656 and 658 may be independently held at a distinct electric potential, generated by a voltage source (not explicitly shown in FIG. 6B for conciseness). Electrodes 656 and 658 may be positioned on top of insulating layer 660-1. Gating layer 652 may be patterned with etched regions 654. Guiding layers 670 and 674 which may also be patterned. Etched regions 654 in gating layer 652 allows the electric field from electrodes 656 and 658 (along with any other repeated electrodes in the same layer) to control the electrochemical potential in active layer 662. Similarly, repeated etched regions 672 in gating layer 670 allow the electric field from repeated gate structures formed by openings 676 in gating layer 674 to further control the electrochemical potential in active layer 662. Active layer 662 may be any conducting or semiconducting layer whose electrical conduction may be controlled by an electrostatic potential applied to various gating layers. In some implementations, active layer 662 may host a two-dimensional electron gas. For example, active layer 662 may be a two-dimensional material whose electronic spectrum has an energy gap. In some implementations, active layer 662 may host, as elementary excitations, non-abelian anyons. In some implementations, layer 670 may be held at a fixed electrostatic potential such that the electrochemical potential in active layer 662 is within the energy gap for most parts of the active layer 662. The electrostatic potential within active layer 662 may be locally lowered (or raised) causing the chemical potential to be within the conduction band (or the valence band) of electrons in active layer 662. As a result, active layer 662 may host a well-defined array of controlled conducting islands or quantum dots where coupling between electrostatically defined quantum dots in the array can be controlled. FIG. 6C illustrates atop view 680 of heterostructure 650 of FIG. 6B.

FIG. 6D shows an example array 690 of quantum dots (QDs) in active layer 662 that can be formed using the techniques of the instant disclosure. The array features two types of QDs, QDs 692 and QDs 694. In some implementations, QDs 692 are used to trap individual charges while QDs 694 are used to facilitate transfer between adjacent QDs 692. The electrochemical potential of an individual QD 692 may be controlled by a corresponding instance of electrode 656, tuned independently of the potentials on all other conducting layers and electrodes. The electrochemical potential of a particular QD 694 may be controlled through a corresponding instance of electrode 658, tuned independently of the potentials on all other conducting layers and electrodes. Control of the electrochemical potential in an individual copy of QDs 694 may be used to control coupling between electrical charges localized in the adjacent QDs 692. In those implementations where QDs 692 are used to localize individual non-abelian anyons, array 690 may be used to implement topological quantum computations through the adiabatic transport of these non-abelian anyons.

FIG. 6E shows an AFM image 695 of an example array of openings made in a graphite guiding layer (e.g., guiding layer 606 of FIG. 6A). FIG. 6E further shows a measured height profile 697 of the three opening (e.g., opening 616, 616-2, and 616-3 of FIG. 6A) located along line 696 of AFM image 695. Data in FIG. 6E were acquired after van der Waals transfer, with the graphite layer already laminated to a hBN layer.

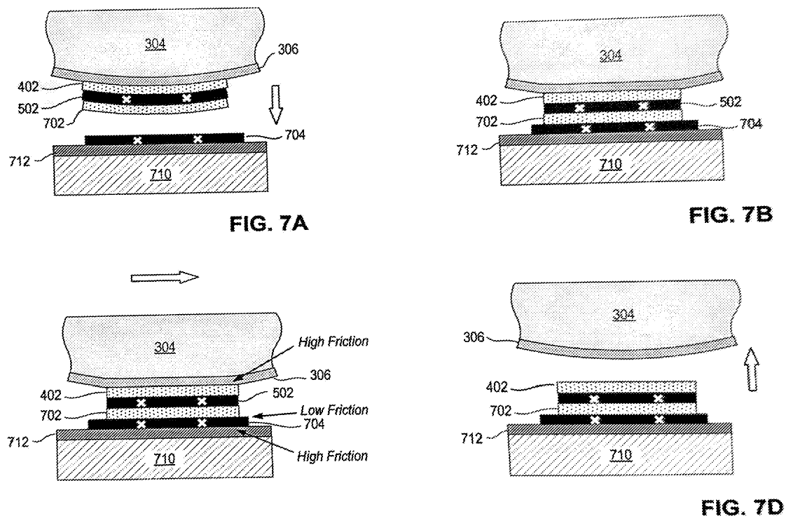

Once multiple layers of a heterostructure are lifted by transfer slide 300, e.g., as described in conjunction with FIGS. 4A-4D and FIG. 5A-5C, the lifted layers may be transferred to another substrate that may host another set of layers, which may have been similarly collected by transfer slide 300 and/or deposited/grown/exfoliated in situ. The two sets of layers may be combined into a single stack, as described below. FIGS. 7A-7D illustrate a process of aggregating sets of fabricated layers into a single heterostructure using a curved lifting surface, in accordance with at least one implementation. As illustrated in FIG. 7A, a first set of layers that includes insulating layer 402, patterned conducting layer 502, and another insulating layer 702 may be carried by dome 304 via adherence to coating film 306. A second set of layers that includes a patterned conducting layer 704 and/or other layers (not shown in FIGS. 7A-7D for conciseness and ease of viewing) may be resting on substrate 710 (and/or substrate coating 712, e.g., SiO₂ film). As the transfer slide 300 moves towards substrate 710, dome 304 presses the two stacks of layers together flattening insulating layers 402, 702 and patterned conducting layer 502, as shown in FIG. 7B.

As further illustrated with FIG. 7B, various patterns (depicted schematically with white crosses) in patterned conducting layer 502 and patterned conducting layer 704 may not align automatically. For example, openings 616-j in guiding layer 606 may be initially misaligned relative to conducting gates 612-j. In some implementations, some or all layers in the heterostructure(s) may be VdW layers having very low mutual friction so that even small strain gradients introduced during stacking and/or aggregation can cause various layers to shift relative to other layers. Aligning different VdW layers using conventional techniques is, therefore, an extremely difficult, if not impossible, task. The techniques disclosed herein may turn this challenge into an advantage. More specifically, the techniques make use of the large difference in low friction between insulating layer 702 (e.g., hBN) and patterned conducting layer 704 (e.g., graphite layer) and large friction between patterned conducting layer 704 and substrate 710 (or substrate coating 712, e.g., SiO₂ film, if present). Additionally, since a tight grip on the first set of layers 402, 502, and 702 is facilitated by coating film 306, a precise sub-micron alignment of patterned features in patterned conducting layers 502 and 704 may be achieved by a lateral motion of dome 304 (mounted on the transfer slide) until the corresponding patterned features in the conducting layers are aligned, as illustrated schematically in FIG. 7C. As dome 304 is lifted, e.g., as illustrated in FIG. 7D, the stack of layers remains attached to substrate 710.

In some implementations, dome 304 and coating film 306 may be heated up to temperatures in the range of 100-200° C., e.g., 170° C. which may be slightly below a glass transition temperature for the material of coating film 306 (e.g., BPA). At such temperatures, coating film 306 may be sufficiently pliable to undergo a plastic deformation. Application of a normal (vertical) force to dome 304 increases friction between coating film 306 and the first set of layers 402, 502, and 702 whereas friction between insulating layer 702 and patterned conducting layer 704 remains low. It has been determined and used in heterostructure assembly processes that a stack of layers that is adhered to coating film 306 maintains formation even though different materials in the stack may have (when not in contact with coating film 306 and the transfer slide) low mutual intrinsic friction. Accordingly, the presence of the transfer slide plays the stabilizing function during sliding illustrated in FIG. 7C. In particular, patterned conducting layer 502 maintains its position relative to coating 306 and dome 304 allowing precise relative alignment with patterned conducting layer 704. Consequently, when dome 304 is moved in the lateral direction (e.g., using micro-manipulators applied to the transfer slide), patterned conducting layers 502 and 704 move relative to each other until the respective patterns reach a target alignment (which may depend on the particular the heterostructure and its specific applications). During the alignment process of FIG. 7C, a relative position of the patterns may be monitored with one or more optical microscopes. In some implementations, the microscope(s) may operate in reflection and may be positioned several millimeters above dome 304. In some implementations, e.g., if substrate 710 and substrate coating 712 are transparent, at least some of the microscope(s) may operate in transmission and may be positioned less than one millimeter below substrate 710. In such implementations, resolution of the microscope(s) may be diffraction limited resulting in alignment accuracy of about 100 nm alignments can be achieved.

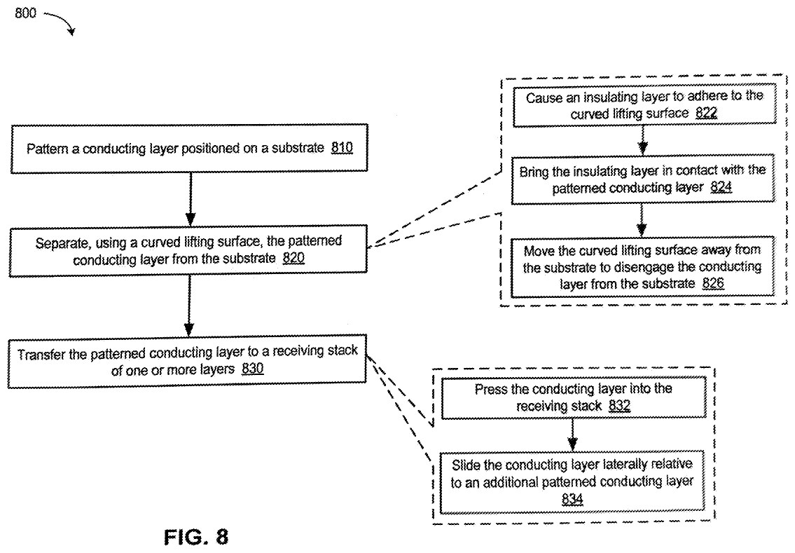

FIG. 8 is a flowchart of an example method 800 of fabricating an ultra-clean heterostructure, in accordance with at least one implementation. Method 800 may be performed using systems and components disclosed above in relation to FIGS. 1-7. Various operations of method 800 may be performed in a different order compared with the order shown in FIG. 8. At block 810, method 800 may include patterning a conducting layer. The conducting layer may be positioned on a substrate. In some implementations, the conducting layer may include a conducting VdW material. In some implementations, the conducting VdW material may include graphite, e.g., a crystal having four or more atomic layers of carbon atoms arranged into a honeycomb crystal lattice (graphene). In some implementations, the conducting layer may include a single-crystal graphene. In some implementations, the conducting layer may include a single-crystal graphite. In some implementations, patterning the conducting layer may include subjecting the conducting layer to AFM local oxidation lithography techniques, e.g., including but not limited to the techniques described in conjunction with FIGS. 2A-2D. In some implementations, patterning the conducting layer may include subjecting the conducting layer to focused ion beam lithography techniques, and/or focused electron beam lithography techniques. In some implementations, patterning the conducting layer may include subjecting the conducting layer to direct ablation caused by focused light beams. In some implementations, the patterned features may have at least one lateral dimension that is less than 500 nm. In some implementations, the patterned features may have total area that is less than 0.25 square microns.

At block 820, method 800 may include separating, using a curved lifting surface, the patterned conducting layer from the substrate. The curved lifting surface may be a surface of one or more components of a transfer slide, e.g., transfer slide 300, including but not limited to the use of the techniques described in conjunction with FIGS. 3A-3C. In some implementations, the curved lifting surface may include a surface of a first polymer material (e.g., surface of coating film 306). For example, the first polymer material may include Bisphenol-A Polycarbonate. In some implementations, the first polymer material may be supported by a second polymer material. In some implementations, the second polymer material may include Poly dimethylsiloxane (PDMS). In some implementations, the second polymer material may be dome-shaped (e.g., dome 304 in FIGS. 3A-3C). In some implementations, the curved lifting surface may have a radius of curvature between 2 mm and 6 mm.

In some implementations, separating the patterned conducting layer from the substrate may include operations illustrated with the top callout portion of FIG. 8. More specifically, at block 822, method 800 may include causing an insulating layer to adhere to the curved lifting surface (e.g., causing insulating layer 402 to adhere to coating film 306, as illustrated in FIGS. 4A-4D). At block 824, method 800 may include bringing the insulating layer in contact with the patterned conducting layer (e.g., bringing insulating layer 402 to in contact with patterned conducting layer 502, as illustrated in FIGS. 5A-5B). At block 826, method 800 may include moving the curved lifting surface away from the substrate to disengage the conducting layer from the substrate (e.g., to disengage patterned conducting layer 502 from substrate 210 and/or substrate coating 404, as illustrated in FIG. 5C). In some implementations, disengaging the conducting layer from the substrate reduces an amount of a chemical residue in the conducting layer (e.g., residue 506, as illustrated in FIG. 5C). In some implementations, the conducting layer may include graphite and the chemical residue may include carbon oxide.

At block 830, method 800 may continue with transferring the patterned conducting layer (e.g., to form a VdW heterostructure). In some implementations, transferring the patterned conducting layer may be performed by the same (or a similar) transfer slide as used in performance of blocks 820-826. In some implementations, transferring the patterned conducting layer may occur to a receiving stack of one or more layers (the receiving layer(s) are referred to as a stack herein even if just one receiving layer is present). In some implementations, the receiving stack includes (at least one) insulating VdW layer. In some implementations, the receiving stack may include an additional patterned conducting layer. For example, as illustrated in FIG. 7A, patterned conducting layer 502 may be transferred to the receiving stack that includes an insulating layer (e.g., insulating layer 702) and an additional patterned conducting layer (e.g., patterned conducting layer 704), but may also include any number of other layers. In some implementations, the insulating VdW later may be made of a material that includes hexagonal boron nitride. In some implementations, transferring the patterned conducting layer may include operations illustrated with the bottom callout portion of FIG. 8. More specifically, at block 832, method 800 may include pressing the conducting layer into the receiving stack (e.g., as illustrated in FIG. 7B). At block 834, method 800 may include sliding the conducting layer laterally relative to the additional patterned conducting layer (e.g., as illustrated in FIG. 7C). Method 800 may then continue with lifting the transfer slide away from the receiving stack to disengage the slide from the resulting heterostructure (e.g., as illustrated in FIG. 7D).

Method 800 may be used to fabricate a number of heterostructures (including VdW heterostructures) and devices that deploy such heterostructures. In one example implementation, a fabricated heterostructure may include a gating layer made (e.g., comprising, consisting of, or consisting essentially of) of single-crystal graphite (e.g., patterned gating layer 602 in FIG. 6A) or made of single-crystal graphene. The gating layer may include one or more cuts 613-1, 613-2, etc., extending through a full thickness of the gating layer (e.g., the cuts depicted with parallel light grey lines across patterned gating layer 602 in FIG. 6A). At least a portion of the one or more cuts 613-1, 613-2 may be free from amorphous carbon and/or carbon oxide, e.g., a central 100 nm×100 nm portion of each cut may be cleaned using the curved dome tool(s) and lifting technique(s), as described in conjunction with FIGS. 3-5, and may be free from agglomerations (blobs) of amorphous carbon and/or carbon oxide larger than 5 nm. In some implementations, the portion cleaned from amorphous carbon and/or carbon oxide may be at least 2 μm×2 μm area and may be free from amorphous carbon and/or carbon oxide agglomerations (blobs) of diameter more than 25 nm. In some embodiments, the process of heterostructure fabrication does not introduce additional dangling bonds to the surface of the insulator in the cuts, so that the density of dangling bonds on the surface of the insulator in the cut regions, as achieved via the described lifting techniques, may be within 10% of the density of dangling bonds on the surface of the insulator away from the cuts. The fabricated heterostructure may further include an insulating layer (e.g., insulating layer 604-1) adjacent to the gating layer, but any number of other insulating layers (e.g., insulating layers 604-2 and 604-3) may also be present. Some or all of the insulating layers may be made of a single-crystal insulating van der Waals (VdW) material.

The fabricated heterostructure may further include an active layer (e.g., active layer 608 in FIG. 6A) made (or comprising or consisting essentially of or consisting of) of a single-crystal gate-tunable VdW material, e.g., a single-crystal semiconducting VdW material. In some implementations, the single-crystal semiconducting VdW material may include a graphene layer, a graphite layer, or a transition metal dichalcogenide material. Conduction in the active layer may be controllable by voltage signals applied (e.g., via electrodes 614-1, 614-2, 614-3 in FIG. 6A) to a plurality of gates (e.g., conducting gates 612-1, 612-2, 612-3 in FIG. 6A) formed in the gating layer by the one or more cuts. It should be understood that a semiconducting VdW material may have any energy gap suitable for a particular purpose for which the fabricated heterostructure is used. In some implementations, the energy gap may be sufficiently small by conventional standards, e.g., energy gaps Δ≈1 meV (or even less) may be used in some instances.

In some implementations, semiconducting VdW material may be or include bilayer graphene. In some implementations, the fabricated heterostructure may further include an additional layer made of single-crystal graphite (e.g., guiding layer 606 in FIG. 6A). The additional layer may have a pattern that is aligned relative to the one or more cuts in the gating layer to a tolerance of 100 nm or even less. For example, openings 616-1, 616-2, 616-3 in guiding layer 606 may be centered (or otherwise aligned) relative to the cuts 613-1, 613-2 in FIG. 6A with the tolerance of 50-100 nm, e.g., using various techniques of optical alignment. In some implementations, the fabricated heterostructure may include any number of other layers (including but not limited to bottom gate layer 610 in FIG. 6A and/or any other suitable layers). In another example implementation, a fabricated heterostructure may be used in a system that includes the fabricated heterostructure and a voltage source to generate a plurality of voltages (e.g., including but not limited to voltages individually applied to electrodes 614-1, 614-2, 614-3 in FIG. 6A). The VdW heterostructure may include a first patterned conducting VdW layer (e.g., a gating layer 602 in FIG. 6A) that includes a plurality of gate islands (e.g., conducting gates 612-1 through 612-3 in FIG. 6A), each of the plurality of gate islands configured to receive a respective one of the plurality of (gate) voltages (e.g., via electrodes 614-1 through 614-3 in FIG. 6A). In some implementations, the first patterned conducting VdW layer may include a first plurality of openings (e.g., portions removed) having at least one lateral dimension that is less than 500 nm (e.g., cuts 613-1 and 613-2 in FIG. 6A). In some implementations, the lateral dimensions of openings may be more than 5 nm. The VdW heterostructure may further include a second conducting VdW layer, such as an active layer, which may be a semiconducting layer (e.g., active layer 608 in FIG. 6A; active layer 662 in FIG. 6B). The VdW heterostructure may also include a third conducting VdW layer (e.g., guiding layer 606 or layer 610 in FIG. 6A; gating layers 652, 670, or 674 in FIG. 6B). The third conducting layer may be patterned. In some implementations, the third conducting layer and the first conducting layer may be disposed on opposite sides from the second VdW layer (e.g., gating layer 602 and bottom gating layer 610 are disposed on opposite sides of active layer 608 in FIG. 6A; gating layers 652 and 670 are disposed on opposite side of active layer 662 in FIG. 6B). In some implementations, the third conducting layer may be disposed between the first conducting layer and the second VdW layer (e.g., gating layer 602 and guiding layer 606 are disposed above active layer 608 in FIG. 6A; gating layer 652 and a layer that hosts electrodes 656 and 658 are disposed above active layer 662 in FIG. 6B). In some implementations, the third patterned conducting VdW layer (e.g., layer 674 in FIG. 6B) may include a second plurality of gate islands, each of the second plurality of gate islands configured to receive a respective one of a second plurality of voltages. In some implementations, the third conducting VdW layer may have a second plurality of openings (e.g., portions removed) having at least one lateral dimension that is less than 500 nm (e.g., gating layer 674 has openings 676 in FIG. 6B). In some implementations, the first plurality of voltages (and/or the first plurality of openings) may be used, alone or in conjunction with the second plurality of voltages (and/or the second plurality of openings), to define a spatially repeating structure of electron states in the second VdW layer. The second plurality of gate islands and/or one or more openings may causing changes in the plurality of gate voltages to modify electrostatic potential within the second VdW layer. In some implementations, the VdW heterostructure may further include a additional insulating VdW layers (e.g., layers 604-1 through 604-3 in FIG. 6A; layers 660-1 through 660-4 in FIG. 6B) located between any of the conducting VdW layers, gating layer(s), guiding layer(s), and/or active layer(s).

In some implementations, the one or more portions removed from the third conducting VdW layer may be arranged into a first superlattice that defines, together with the plurality of gate islands of the first conducting VdW, a second superlattice of quantum dots in the second VdW layer. For example, the first superlattice of removed portions may be arranged into a suitable superlattice (configured to induce a matching superlattice in the second VdW layer), e.g., square superlattice, a rectangular superlattice, a triangular superlattice, a honeycomb superlattice, or any other suitable superlattice. In some implementations, the one or more quantum dots of the second superlattice of quantum dots may support one or more qubits of a quantum computer operation performed by the system.

Any, all, or some operations of method 800 and/or other methods that are similar to method 800 may be performed responsive to instructions by a processing logic that may include hardware (e.g., circuitry, dedicated logic, programmable logic, microcode, etc.), software, firmware or a combination thereof.

It should be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The implementations of methods, hardware, software, firmware or code set forth above may be implemented via instructions or code stored on a machine-accessible, machine readable, computer accessible, or computer readable medium which are executable by a processing element coupled to memory. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium: flash memory devices; electrical storage devices: optical storage devices; acoustical storage devices, and any type of tangible machine-readable medium suitable for storing or transmitting electronic instructions or information in a form readable by a machine (e.g., a computer).

Reference throughout this specification to “one implementation” or “an implementation” means that a particular feature, structure, or characteristic described in connection with the implementation is included in at least one implementation of the disclosure. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

In the foregoing specification, a detailed description has been given with reference to specific exemplary implementations. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of implementation, embodiment, and/or other similar language does not necessarily refer to the same implementation or the same example, but may refer to different and distinct implementations, as well as potentially the same implementation.

The words “example” or “exemplary” are used herein to mean serving as an example, instance or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A: X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an implementation” or “one implementation” throughout is not intended to mean the same embodiment or implementation unless described as such. Also, the terms “first,” “second,” “third,” “fourth,” etc. as used herein are meant as labels to distinguish among different elements and may not necessarily have an ordinal meaning according to their numerical designation.

What is claimed is:

1. A method comprising:
patterning a conducting van der Waals (VdW) layer positioned on a substrate with one or more patterned features having area that is less than 0.25 square micrometers;
separating, the patterned conducting VdW layer from the substrate; and
transferring the patterned conducting VdW layer to a receiving stack of one or more layers.

2. The method of claim 1, wherein the receiving stack comprises an insulating VdW layer.

3. The method of claim 2, wherein the conducting VdW layer comprises a single-crystal graphene or a single-crystal graphite, and wherein the insulating VdW later comprises hexagonal boron nitride.

4. The method of claim 1, wherein patterning the conducting VdW layer comprises subjecting the conducting VdW layer to at least one of:
atomic force microscope (AFM) local oxidation lithography,
focused ion beam lithography,
focused electron beam lithography, or
ablation by one or more light beams.

5. The method of claim 1, wherein separating the patterned conducting VdW layer from the substrate comprises lifting the patterned conducting VdW layer with a curved lifting surface, wherein the curved lifting surface comprises a surface of a first polymer material.

6. The method of claim 5, wherein the first polymer material is supported by a second polymer material, wherein the second polymer material is dome-shaped.

7. The method of claim 6, wherein the first polymer material comprises Bisphenol-A Polycarbonate and the second polymer material comprises Polydimethylsiloxane.

8. The method of claim 5, wherein the curved lifting surface has a radius of curvature between 2 mm and 6 mm.

9. The method of claim 5, wherein separating the patterned conducting VdW layer from the substrate comprises:
causing an insulating layer to adhere to the curved lifting surface;
bringing the insulating layer in contact with the patterned conducting VdW layer; and
moving the curved lifting surface away from the substrate to disengage the conducting VdW layer from the substrate.

10. The method of claim 9, wherein disengaging the conducting VdW layer from the substrate reduces an amount of a chemical residue in the conducting VdW layer.

11. The method of claim 10, wherein the conducting VdW layer comprises a graphene layer or a graphite layer and wherein the chemical residue comprises at least one of carbon oxide or amorphous carbon.

12. The method of claim 1, wherein the receiving stack of one or more layers comprises an additional patterned conducting layer, and wherein transferring the patterned conducting VdW layer to the receiving stack comprises:
pressing the conducting VdW layer into the receiving stack; and
sliding the conducting VdW layer laterally relative to the additional patterned conducting layer.

13. A heterostructure comprising:
a gating layer made of single-crystal graphene or single-crystal graphite, wherein the gating layer comprises one or more cuts extending through a full thickness of the gating layer, and wherein at least a portion of the one or more cuts is free from carbon oxide or amorphous carbon; and
an insulating layer adjacent to the gating layer, wherein the insulating layer is made of a single-crystal insulating van der Waals (VdW) material.

14. The heterostructure of claim 13, further comprising:
an active layer made of a single-crystal semiconducting VdW material wherein conduction in the VdW material is controllable by voltage signals applied to a plurality of gates formed in the gating layer by the one or more cuts.

15. The heterostructure of claim 14, wherein the semiconducting VdW material comprises at least one of:
a graphene layer,
a graphite layer, or
a transition metal dichalcogenide material.

16. The heterostructure of claim 13, further comprising:
an additional layer made of single-crystal graphene or single-crystal graphite, wherein the additional layer comprises a pattern aligned relative to the one or more cuts in the gating layer.

17. A system comprising:
a voltage source to generate a first plurality of voltages; and
a van der Waals (VdW) heterostructure, comprising:
a first patterned conducting VdW layer comprising at least one of:
a first plurality of gate islands, each of the first plurality of gate islands configured to receive a respective one of the first plurality of voltages, or
a first plurality of openings, each of the first plurality of openings having at least one lateral dimension that is less than 500 nm;
a second VdW layer; and
a third patterned conducting VdW layer.

18. The system of claim 17, wherein the first patterned VdW conducting layer and the third VdW conducting layer are disposed on opposite sides of the second VdW layer.

19. The system of claim 17, wherein the third patterned conducting VdW layer comprises at least one of:
a second plurality of gate islands, each of the second plurality of gate islands configured to receive a respective one of a second plurality of voltages, or
a second plurality of openings, each of the second plurality of openings having at least one lateral dimension that is less than 500 nm.

20. The system of claim 17, wherein the first plurality of voltages is used to define a spatially repeating structure of electron states in the second VdW layer.
